(19) United States
(12) Patent Application Publication
(10) Pub. No.: US 2018/0277342 A1
(43) Pub. Date: Sep. 27, 2018

(54) SPUTTERING TARGET AND METHOD FOR PRODUCING THE SAME

(71) Applicant: JX Nippon Mining & Metals Corporation, Tokyo (JP)

(72) Inventors: Kozo Osada, Ibaraki (JP); Yoshitaka Tsuruta, Ibaraki (JP); Satoru Tateno, Ibaraki (JP)

(21) Appl. No.: 15/888,150

(22) Filed: Feb. 5, 2018

(30) Foreign Application Priority Data
Mar. 22, 2017 (JP) 2017-056493

(51) Int. Cl. H01J 37/34; C23C 14/34; C23C 14/08

(52) U.S. Cl. CPC H01J 37/3435; C23C 14/3407; H01J 37/3417; C23C 14/086; H01J 37/3426; C23C 14/3464

(57) ABSTRACT

Provided is a sputtering target that can ensure a required thickness of a bonding material and improve the quality, even if the backing tube is curved and deformed in the axial direction; and a method for producing the same.

A sputtering target according to the present invention comprises a target material made of a ceramic material and comprising a plurality of cylindrical target segments arranged side by side at an interval of from 0.15 mm to 0.50 mm in the axial direction; a cylindrical backing tube arranged on the inner peripheral side of the target material; and a bonding material interposed between the target material and the backing tube to bond the target material to the backing tube, wherein a quantity of step difference between outer end edges adjacent to each other in the axial direction on the respective outer peripheral surfaces of at least a pair of target segments adjacent to each other in the axial direction is 0.50 mm or less as measured along the radial direction, and wherein the thickness of the bonding material is changed in at least a part of the axial direction within at least one target segment, and the bonding material in the at least one target segment comprises a minimum thickness of 0.6 mm or more and 1.4 mm or less.

### TECHNICAL FIELD

The present invention relates to a sputtering target comprising a target material comprising a plurality of cylindrical target segments arranged side by side in an axial direction; a cylindrical backing tube arranged on an inner peripheral side of the target material; and a bonding material for bonding the target material to the backing tube between them, and to a method for producing the same. More particularly, the present invention proposes a technique that can still maintain a required thickness of the bonding material even when the backing tube curved and deformed in the axial direction is repeatedly used or the like, thereby contributing to improvement of the quality of the sputtering target.

### BACKGROUND ART

For example, a magnetron sputtering using a flat sputtering target with a target material bonded onto a flat backing plate is mainly employed for sputtering to form a transparent conductive thin film made of ITO, IZO, or the like when producing a display device such as an organic EL, a liquid crystal display, a touch panel or the like. In addition, rotary sputtering is put into practical use. In the rotary sputtering, a cylindrical sputtering target in which a target material is bonded to an outer peripheral surface of a cylindrical backing tube is rotated around the axis to perform the sputtering.

Recently, the dimensions of displays and the like have been increased. Correspondingly, there is a need for a cylindrical sputtering target for sputtering a thin film, which has a larger length in the axial direction.

Such a larger cylindrical sputtering target is liable to be cracked or deformed during molding due to the higher length of the target material, and it is thus difficult to produce the target material as a single body.

Therefore, the sputtering target is generally produced by molding a plurality of target segments obtained by dividing a target material into a plurality of pieces in the axial direction, arranging the plurality of target segments on the outer peripheral side of the backing tube so as to array the target segments in the axial direction, and bonding them via a bonding material, for example, as described in Patent Documents 1 and 2.

### CITATION LIST

### Patent Literatures

Patent Document 1: Japanese Patent Application Publication No. 2010-100930 A1

Patent Document 2: WO 2016/067717

### SUMMARY OF INVENTION

### Technical Problem

In the cylindrical sputtering target as described above, after being used in the rotary sputtering, only the target material shaved by sputtering may be replaced with a new one, and the backing tube may be repeatedly used. Such a backing tube may be curved and deformed by warping in at least a part of the axial direction due to repeated use.

Here, when the target material is arranged on the outer peripheral surface of the backing tube that has been curved and deformed due to repeated use and they are bonded via the bonding material supplied therebetween, the size of a gap between the backing tube and the target material will partially vary, thereby changing the thickness of the bonding material in the axial direction or the circumferential direction.

However, such a change in the thickness of the bonding material causes a problem such as a cause of cracks during the sputtering, which is undesirable. Further, the uneven thickness of the bonding material leads to voids generated in the bonding material made of indium or the like, or increased tendency of residual indium oxide, which will also be a factor to destabilize the quality of bonding.

Patent Document 2 focuses attention on the eccentricity between the substrate and the target material, and discloses that in order to suppress this, the warp of the cylindrical substrate is confirmed prior to production of the cylindrical target, and the warp of the cylindrical substrate is corrected by using a press machine or the like when the warp is larger.

However, when the warp of the cylindrical substrate has been forcibly corrected in such a way, the cylindrical substrate does not have the original circular cylindrical shape. Accordingly, if one tries to surely eliminate the warp, a large stress may be generated during the correction to cause cracking.

Patent Document 2 also discloses that the warp of the cylindrical substrate is reduced to 0.6 mm or less by the correcting step as described above. However, even if the warp is reduced to 0.6 mm or less, the warp is present in the cylindrical substrate, so that it is inevitable that the size of the gap between the cylindrical substrate and the target material disposed on the outer peripheral side of the cylindrical substrate is changed in the circumferential direction or the axial direction. As a result, the thickness of the bonding material interposed therebetween is also partially changed such that a locally thin portion is generated, and so on.

Therefore, the problem caused by the change in the thickness of the bonding material generated by the curved deformation of the backing tube would not be able to be sufficiently addressed by the warp correction technique as described in Patent Document 2.

On the other hand, when each target segment is arranged on the outer peripheral side of the backing tube prior to bonding so as to ensure the required thickness of the bonding material, a larger step difference may be generated between the target segments adjacent to each other in the axial direction. In this case, arcing occurs at a portion with the larger step difference between the target segments during the sputtering, thereby causing chipping and cracking and making it impossible to continue to use the sputtering target.

An object of the present invention is to solve such problems of the prior arts, and to provide a sputtering target that can ensure the required thickness of the bonding material and improve the quality, even if the backing tube is curved and deformed in the axial direction; and a method for producing the same.

### Solution to Problem

A sputtering target according to the present invention comprises: a target material made of a ceramic material and comprising a plurality of cylindrical target segments arranged side by side at an interval of from 0.15 mm to 0.50 mm in an axial direction; a cylindrical backing tube arranged on an inner peripheral side of the target material; and a bonding material interposed between the target material and the backing tube to bond the target material to the backing tube, wherein a quantity of step difference between outer end edges adjacent to each other in the axial direction on respective outer peripheral surfaces of at least a pair of target segments adjacent to each other in the axial direction is 0.50 mm or less as measured along a radial direction, and wherein a thickness of the bonding material is changed in at least a part of the axial direction within at least one target segment, and the bonding material in the at least one target segment comprises a minimum thickness of 0.6 mm or more and 1.4 mm or less.

In the sputtering target according to the present invention, the bonding material may preferably have a variation of the thickness in the axial direction within the at least one target segment of 0.8 mm or less.

In the sputtering target according to the present invention, the bonding material in the at least one target segment may preferably have a minimum thickness of 0.7 mm or more.

Further, in the sputtering target according to the present invention, when the backing tube is placed sideways on a surface plate, a maximum distance between the smooth surface of the surface plate and the outer peripheral surface of the backing tube may preferably be 0.5 mm or less.

The sputtering target according to the present invention may preferably have a ratio of a length of the target segment to a length of the backing tube in a longitudinal direction of 0.3 or less.

A method for producing a sputtering target according to the present invention comprises a segment arranging step of arranging side by side a plurality of cylindrical target segments made of a ceramic material in an axial direction around a cylindrical backing tube; a bonding material filling step of filling a gap between the backing tube and the target segments with a bonding material in a molten state; and a cooling step of cooling the bonding material and bonding the target segments to a circumference of the backing tube by the bonding material to form a target material, wherein the method comprises using the backing tube curved and deformed in at least a part of the axial direction, and wherein the method further comprises a deformation quantity measuring step of measuring a quantity of deformation of the backing tube, prior to the segment arranging step, wherein the segment arranging step comprises arranging the respective target segments, such that a size of the gap between the backing tube and at least one target segment is 0.6 mm or more and 1.6 mm or less as measured along a radial direction, by adjusting the size of the gap between the backing tube and the at least one target segment depending on the quantity of deformation of the backing tube, and a quantity of step difference between outer end edges adjacent to each other in the axial direction on respective outer peripheral surfaces of at least a pair of target segments adjacent to each other in the axial direction is 0.50 mm or less as measured along the radial direction.

In the method for producing the sputtering target according to the present invention, the method may preferably comprise producing the sputtering target comprising a variation of a thickness of the bonding material in the axial direction within at least one target segment of 0.8 mm or less.

In the method for producing the sputtering target according to the present invention, the method may preferably comprise producing the sputtering target comprising a minimum thickness of the bonding material in the at least one target segment of 0.6 mm or more.

The segment arranging step may preferably comprise adjusting the size of the gap between the backing tube and the target segments to 0.7 mm or more as measured along the radial direction.

The deformation quantity measuring step may preferably comprise placing the backing tube on a surface plate sideways, and measuring a distance between the smooth surface of the surface plate and the outer peripheral surface of the backing tube, and wherein the maximum distance between the smooth surface and the outer peripheral surface is 0.5 mm or less.

### Advantageous Effects of Invention

According to the sputtering target of the present invention, the required thickness of the bonding material between the target segments and the backing tube can be maintained to improve the quality of the sputtering target, because the minimum thickness of the bonding material in at least one target segment is 0.6 mm or more and 1.4 mm or less, even if the backing tube is curved and deformed in at least a part of the axial direction such that the thickness of the bonding material is changed in the axial direction in at least a part of the axial direction within the at least one target segment.

Further, since the step difference between the outer edges of at least a pair of target segments adjacent to each other in the axial direction is 0.50 mm or less as measured along the radial direction, the probability of arcing generated during sputtering due to the step difference can be effectively reduced.

According to the method for producing the sputtering target of the present invention, it is possible to produce the sputtering target that can maintain the required thickness of the bonding material and have decreased step difference, because in the deformation quantity measuring step prior to the segment arranging step, the quantity of deformation of the backing tube is measured, and in the segment arranging step, the size of the gap between the backing tube and the target segments is adjusted by controlling the position of the target segments on the outer peripheral side depending on the measured quantity of the deformation of the backing tube such that the size of the gap is 0.6 mm or more and 1.4 mm or less, and each target segment is arranged such that the quantity of the step between the outer end edges of at least a pair of target segments adjacent to each other in the axial direction is 0.50 mm or less as measured along the radial direction.

### BRIEF DESCRIPTION OF DRAWINGS

FIG. 1 is a perspective view conceptually showing a sputtering target according to one embodiment of the present invention.

FIG. 2 is a partially enlarged perspective view of the sputtering target of FIG.

FIG. 3 is a perspective view conceptually showing a sputtering target of Comparative Example.

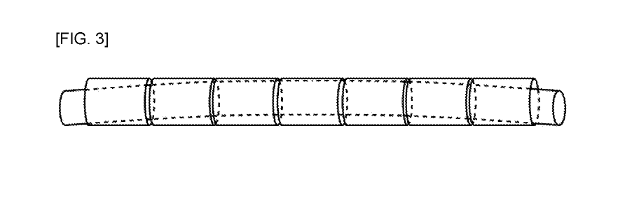

### DESCRIPTION OF EMBODIMENTS

Hereinafter, embodiments of the present invention will be described in detail with reference to the drawings.

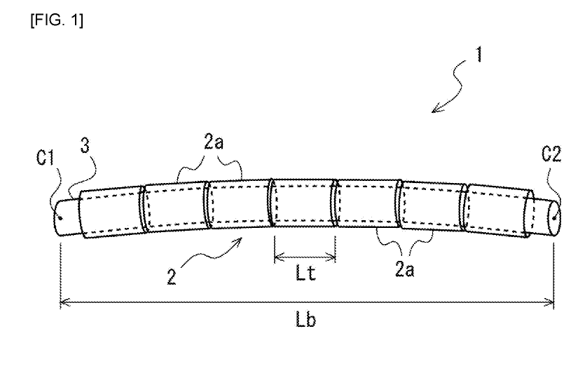

A sputtering target 1 of an embodiment illustrated in FIG. 1 is made of a ceramic material and includes a target material 2 having a plurality of cylindrical target segments 2a arranged side by side at an interval of from 0.15 mm to 0.50 mm in the axial direction; a cylindrical backing tube 3 disposed on the inner peripheral side of the target material 2; and a bonding material (not shown) interposed between the target material 2 and the backing tube 3 to bond the target material 2 to the backing tube 3.

In the sputtering target 1, the thickness of the bonding material is changed in the axial direction in at least a part of the axial direction within at least one target segment 2a. The minimum thickness of the bonding material in at least one target segment 2a is 0.6 mm or more and 1.4 mm or less. That is, in the at least one target segment 2a, the thickness of the bonding material filled and interposed between the target segment 2a and the backing tube 3 is 0.6 mm or more and 1.4 mm or less, at any position in the circumferential direction and in the axial direction, as measured in the radial direction.

Further, the quantity of step difference between the outer edges of at least a pair of target segments 2a adjacent to each other in the axial direction is 0.50 mm or less as measured along the radial direction.

### (Backing Tube)

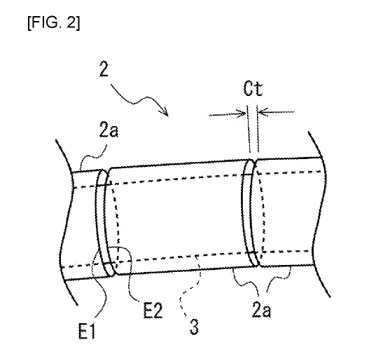

In the sputtering target 1 according to the embodiment of the present invention, the backing tube 3 is curved and deformed in at least a part of the axial direction, as shown in an exaggerated manner in FIG. 1. As can be seen from the enlarged view shown in FIG. 2, in at least a part of the axial direction within at least one target segment 2a, the size of a gap between the outer peripheral surface of the backing tube 3 whose central axis is curved and the target segment 2a whose central axis is straight is changed in the axial direction, so that the thickness of the bonding material filled in the gap and interposed between the backing tube 3 and the target material 2 is changed in the axial direction.

When a part of the outer peripheral surface of the backing tube 3 is brought into contact with a surface plate and placed on the surface plate sideways, the backing tube 3 may be preferably curved in such a quantity that a distance between the smooth surface of the surface plate and the outer peripheral surface of the backing tube is at most 0.5 mm or less as measured along the perpendicular line erected on the surface plate. If the maximum value of the distance at a position furthest away from the smooth surface of the surface plate is more than 0.5 mm, the quantity of deformation of the backing tube will be too high, so that an excessively thinner portion and an excessively thicker portion of the bonding material will be generated between the target segment 2a and the backing tube 3, which may cause cracks during sputtering and poor adhesion during bonding. Therefore, the maximum distance between the smooth surface of the surface plate and the outer peripheral surface of the backing tube may be more preferably 0.4 mm or less, and even more preferably 0.3 mm or less.

However, since the backing tube 3 is arranged inside the target material 2, it is difficult to measure the curved deformation of the backing tube 3 by visual observation or a measuring instrument such as vernier caliper and a depth gauge in the state of the sputtering target 1 in which the target material 2 is bonded onto the outer peripheral side of the backing tube 3. Therefore, in the state of the sputtering target 1 in which the target material 2 is bonded onto the outer peripheral side of the backing tube 3, the curved deformation of the backing tube 3 is confirmed by a change of the thickness of the bonding material interposed between the target segment 2a and the backing tube 3 in the axial direction.

The change of the thickness of the bonding material in the axial direction can be confirmed by referring to a peak interval between a back surface wave of the target segment 2a and a surface wave of the backing tube 3 in a waveform diagram obtained by an ultrasonic inspection.

The curved deformation of the backing tube 3 means that the central axis line of the backing tube 3 which is a collection of the central points in the circular cross section with respect to the outer peripheral surface of the backing tube 3 is curved in the longitudinal direction. Such a curvature of the central axis line includes, in addition to the curvature in a substantially circular arc form as shown in the figures, various conditions such as a combination of a plurality of substantially circular arc curves, local curves, or a plurality of bent portions. In the backing tube 3, a straight portion may be present in a part of the center axis line, but at least a part of the straight portion should be curved. The present invention is directed to the sputtering target 1 having such a curved and deformed backing tube 3.

On the other hand, each of the target segments 2a has an inner diameter larger than the outer diameter of the backing tube 3, and has a substantially straight central axis line as a correction of the central points in the circular cross section with respect to the inner peripheral surface of the target segment 2a. Therefore, when such a target segment 2a is arranged on the outer peripheral side of the backing tube 3, the size of a gap between the outer peripheral surface of the curved and deformed backing tube 3 and the inner peripheral surface of the target segment 2a parallel to the straight central axis line and the thickness of the bonding material closely filled in the gap will be changed in the axial direction, as shown in FIG. 2.

It should be note that the material of the backing tube 3 is not particularly limited as long as the backing tube 3 is curved and deformed as described above, and for example, the material includes Ti, SUS, Cu, or the like.

### (Target Material)

The target material 2 includes a plurality of cylindrical target segments 2a, and is formed by arranging side by side these target segments 2a in the axial direction on the outer peripheral side of the backing tube 3. In other words, the target material 2 is divided into a plurality of cylindrical target segments 2a in the axial direction of the backing tube 3.

Each of the plurality of target segments 2a is arranged at each arrangement position on the outer peripheral side of the backing tube 3, such as by inclining the central axis line or moving the central axis line toward the radial direction at any position in the circumferential direction, in accordance with the curved deformation of the backing tube 3 at that arrangement position. Thus, the required thickness of the bonding material between the inner peripheral surface of the target segment 2a and the outer peripheral surface of the backing tube 2 can be maintained as will be described below.

In the longitudinal direction of the sputtering target 1, the target segments 2a may have a length Lt along the central axis line of 0.3 or less per one target segment 2a, as expressed as a ratio to a length Lb of the backing tube 3.

That is, this is because when the ratio of the length Lt of the target segment 2a to the length Lb of the backing tube 3 is too large, the target segment 2a will be long, so that there are concerns that the curved deformation of the backing tube cannot be completely absorbed by adjusting the positions of the target segments 2a, and the required thickness of the bonding material cannot be maintained. It should be noted that the length Lb of the backing tube 3 means a linear distance between the central points C1 and C2 in the cross section from one end to other end of the backing tube 3, as shown in FIG. 1.

Since the arrangement positions of the target segments 2a are adjusted as described above, a pair of target segments 2 may generate a step difference in the radial direction due to the mutual deviation of the target segments 2a in the radial direction, between the outer end edges E1 and E2 adjacent to each other in the axial direction on the respective outer peripheral surfaces of the pair of target segments 2a adjacent to each other in the axial direction.

In this case, a quantity of the step difference between the outer end edges E1 and E2 adjacent to each other in the axial direction on the respective outer peripheral surfaces of at least one pair of target segments adjacent to each other in the axial direction should be 0.50 mm or less at any position in the circumferential direction, as measured along the radial direction. If the maximum value of the quantity of the step difference between the outer edges E1 and E2 is more than 0.50 mm, arcing will occurs at the step portion during sputtering, so that chipping and cracking will occur accordingly, and continued use will be impossible. Therefore, the quantity of the step difference between the outer edges E1 and E2 may preferably be 0.50 mm or less, and more preferably 0.3 mm or less. There is no particular disadvantage for a smaller quantity of the step between the outer edge E1 and E2, but it may be 0.10 mm or more in some cases.

The quantity of the step difference is measured using a depth gauge.

The axial distance Ct between the target segments 2a adjacent to each other in the axial direction should be from 0.15 mm to 0.50 mm. This is because if the distance Ct is less than 0.15 mm, the end portions may be brought into contact with each other due to thermal expansion during sputtering to generate chipping and cracking, and if the distance is more than 0.50 mm, it may cause an increase in particles on the substrate during sputtering. The distance Ct may preferably be from 0.20 mm to 0.30 mm.

The distance Ct in the axial direction is measured using a filler gauge.

It is understood that the target material 2, that is, each target segment 2a, is made of a ceramic material. Specific examples of the ceramic material include, for example, ITO, IZO, IGZO and the like.

### (Bonding Material)

Although not shown, a bonding material is interposed between the backing tube 3 and each target segment 2a of the target material 2, whereby the backing tube 3 and each target segment 2a are bonded to each other.

As will be described below, the bonding material is supplied in a molten state to the gap between the backing tube 3 and each target segment 2a disposed at a predetermined position on the outer peripheral side of the backing tube 3 during production of the sputtering target 1, and cured after being filled in the gap to bond the backing tube 3 to each target segment 2a. Therefore, the thickness of the bonding material corresponds to the size of the gap between the backing tube 3 and each target segment 2a.

In the present invention, the minimum thickness of the bonding material interposed between the at least one target segment 2a and the backing tube 3 should be 0.6 mm or more and 1.4 mm or less as measured along the radial direction. Therefore, the required thickness of the bonding material is maintained over the entire circumferential and axial directions of the target segment 2a, so that generation of cracks during sputtering due to the locally thinner portion of the bonding material can be effectively prevented, as well as degradation of bonding quality due to generation of voids in the bonding material, remaining indium oxide or the like can also be prevented.

The minimum thickness of the bonding material in the target segments 2a may preferably be 0.7 mm or more, and more preferably 0.8 mm or more, in terms of sufficiently ensuring the required thickness of the bonding material. On the other hand, there is no particular disadvantage even if the minimum thickness of the bonding material is too high, but the minimum thickness of the bonding material in the target segments 2a may be 1.4 mm or less.

More preferably, the minimum thickness of the bonding material interposed between all the target segments 2a of the target material 2 and the backing tube 3 is 0.6 mm or more.

The minimum thickness of the bonding material is measured from a peak interval of a back surface wave of the target segment 2a and a surface wave of the backing tube 3 in a waveform diagram obtained by an ultrasonic inspection.

More particularly, an ultrasonic flaw detection device is used to transmit an A wave (the back surface wave of the target segment 2a) that arrives at and reflects from a boundary surface between the target material 2 and the bonding material from the outer peripheral surface of the target material 2 defining the outer peripheral surface of the sputtering target 1 and a B wave (the surface wave of the backing tube 3) that arrives at and reflects from a boundary surface between the bonding material and the backing tube, and to propagate the waves in the radial direction. The thickness Tb of the bonding material can be calculated from the equation: Tb=½×Vs×Dt, in which Dt is a difference in detection times after reflection of each of the A wave and the B wave and Vs is a sound speed in the bonding material based on the composition of the bonding material. In addition, if the bonding material is made of In metal, the sound speed Vs in the bonding material is 2700 mm/sec.

The thickness of the bonding material is measured at total five points of two points spaced inward away from each of the both ends of the target segment 2a by 10 mm and three points obtained by equally dividing the space between the two points into four parts, per one target segment 2a, in the axial direction. At each of the measurement points in the axial direction, the measurement is carried out at twelve positions at an interval of 30° in the circumferential direction (positions of 0°, 30°, 60°, . . . and 330°). Among these measured values thus obtained, the smallest value is defined as the minimum thickness of the bonding material. It should be noted that a stamp or other mark regarding a number or the like may be provided at any portion of the backing tube 3, and in this case, the measurement is carried out using the mark as a reference (that is, the position where the mark is present is considered to be 0°) at each position at an interval of 30° in the circumferential direction.

It is also suitable that a variation of the thickness of the bonding material in the axial direction within at least one target segment 2a is 0.8 mm or less. In other words, if the variation of the thickness of the bonding material in the axial direction in the target segment 2a is more than 0.8 mm, there is a concern about the aforementioned disadvantage due to the excessively thinner and thicker portions of the bonding material.

The variation of the thickness of the bonding material in the axial direction in the target segment 2a is calculated by an ultrasonic inspection.

More preferably, in all the target segments 2a of the target material 2, the variation of the thickness of the bonding material in the axial direction in the target segments 2a is within the range as described above.

Such a minimum thickness and variation of the thickness of the bonding material can be achieved by adjusting the position of each target segment 2a relative to the backing tube 3 during producing the sputtering target 1, thereby adjusting the distance between the backing tube 3 and each target segment 2a.

The material of the bonding material is not particularly limited as long as it can be used for bonding the kinds of target material 2 and the backing tube 3, and examples of the material include In metal, In—Sn metal, In alloy metal in which a trace metal component(s) is added to In, and the like.

### (Producing Method)

The sputtering target 1 as described above can be produced, for example, as follows:

First, a plurality of cylindrical target segments 2a made of a ceramic material and the backing tube 3 curved and deformed in at least a part of the axial direction are prepared. The methods for manufacturing these target segment 2a and backing tube 3 are widely known, and the known methods can be employed.

Then, a deformation quantity measuring step is carried out for measuring the quantity of deformation of the backing tube 3. Here, the backing tube 3 can be placed on a surface plate sideways, and a distance between the smooth surface of the surface plate and the outer peripheral surface of the backing tube can be measured along the perpendicular line erected on the surface plate. It is suitable that the maximum value of the measured distance between the smooth surface of the surface plate and the outer peripheral surface of the backing tube is 0.5 mm or less as described above.

Here, if the maximum value of the distance between the flat surface of the surface plate and the outer peripheral surface of the backing tube is more than 0.5 mm, the backing tube 3 can be subjected to a correcting treatment to correct the distance such that the maximum value is 0.5 mm or less. The correcting treatment can be carried out, for example, by mechanical pressing correction, or in some cases by further performing a heat treatment (annealing).

Subsequently, a segment arranging step is carried out. In the segment arranging step, the respective target segments 2a are arranged side by side in the axial direction on the outer peripheral side of the backing tube 3 such that the respective target segments 2a surround the backing tube 3.

Here, in the segment arranging step, it is important to adjust the size of the gap between the backing tube 3 and each target segment 2a according to the quantity of deformation of the backing tube 3 measured in the deformation quantity measurement step.

More particularly, the size of the gap is adjusted such as by inclining the central axis line of the target segment 2a or moving the central axis line toward the radial direction at any position in the circumferential direction, such that the radial distance between the outer peripheral surface of the backing tube 3 and the inner peripheral surface of the target segment 2a is 0.6 mm or more and 1.4 mm or less, and preferably 0.7 mm or more, and more preferably 0.8 mm or more, even at any point in the circumferential direction and the axial direction of the target segment 2a. In such a way, the minimum thickness of the bonding material in the sputtering target 1 to be produced can be 0.6 mm or more, and preferably 0.7 mm or more. It is also possible to obtain the sputtering target 1 having decreased variation of the thickness of the bonding material in the axial direction within at least one target segment 2a.

In this case, due to the above adjustment of the size of the gap, a step difference may be generated between the outer edges adjacent to each other in the axial direction on the respective outer peripheral surfaces of a pair of target segments 2a adjacent to each other in the axial direction. In this case, the quantity of the step difference should be 0.50 mm or less as measured along the radial direction. The reason is as described above.

The segment arranging step is followed by a bonding material filling step of filling a gap between the backing tube 3 and the target segments 2a with the bonding material in a molten state, followed by a cooling step of cooling the bonding material and bonding the respective target segments to the circumference of the backing tube via the bonding material to form a target material. In the bonding material filling step, for example, the bonding material in a molten state is poured into the gap between the backing tube 3 and each target segment 2a. Here, the gap adjusted as described above between the backing tube 3 and each target segment 2a defines the thickness of the cured bonding material through the cooling step.

These bonding material filling step and cooling step can be carried out by various methods including known methods.

### Examples

The sputtering target according to the present invention was experimentally produced and its effects were confirmed as described below. However, the description herein is merely for the purpose of illustration and is not intended to be limited thereto.

As shown in Table 1, a target material comprised of a predetermined number of ITO target segments each having φ153 mm (135 mm), a thickness of 9 mm and a length as shown in Table 1 was combined with a backing tube (substrate) having a length of 2940 mm or 1624 mm to produce each of sputtering targets of Examples 1 to 5 and Comparative Examples 1 to 5. The quantity of deformation of the backing tube was measured beforehand on the surface plate, and the warp was as shown in Table 1.

### (Thickness of Bonding Material)

As the adhesion rate of the sputtering target of each of Examples and Comparative Examples was measured by the ultrasonic inspection, the thickness of the bonding material at each position was confirmed by the method as described above. The ultrasonic test equipment used herein was FSLINE Hybrid available from Hitachi Power Solutions Co., Ltd., using a probe with 10 MHz. Table 1 shows the thickness difference at the ends and the center in a single target segment, the minimum thickness, the maximum thickness and the variation.

### (Evaluation of Sputtering)

The sputtering targets of Examples 1 to 5 and Comparative Examples 1 to 5 were sputtered under the following conditions, demonstrating that in the sputtering targets of Examples 1 to 5, the number of target segments for which the generation of cracks was confirmed was zero. However, after evaluating the sputtering targets of Comparative Examples 1 to 5, their appearances were observed and the generation of cracks was observed at a specific portion (a portion where the bonding material was extremely thinner) of one or more target segments.

### (Sputtering Conditions)

### Sputtering Gas: Ar;

### Sputtering Pressure: 0.6 Pa;

Flow Rate of Sputtering Gas: 300 sccm; and

### Sputtering Power: 4.0 W/cm².

TABLE 1

| | | | | Evaluation of Thickness of Bonding Material | | | |
|---|---|---|---|---|---|---|---|
| | | | | Difference | | | |
| | | | | between | | | |
| | Evaluation between Segments | | | End and | | | |
| | | | Maximum | Center in | | | |
| | Maximum | Minimum | Step | Single | Minimum | Maximum | |
| | Distance/ | Distance/ | Difference/ | Segment/ | Thickness/ | Thickness/ | Variation/ |
| | mm | mm | mm | mm | mm | mm | mm |
| Example 1 | 0.30 | 0.25 | 0.05 | 0.0 | 1.0 | 1.0 | 0.0 |
| Example 2 | 0.30 | 0.20 | 0.15 | 0.2 | 0.8 | 1.2 | 0.4 |
| Example 3 | 0.30 | 0.20 | 0.20 | 0.2 | 0.7 | 1.3 | 0.6 |
| Example 4 | 0.30 | 0.25 | 0.05 | 0.3 | 0.7 | 1.3 | 0.6 |
| Example 5 | 0.35 | 0.25 | 0.10 | 0.2 | 0.8 | 1.2 | 0.4 |
| Comparative | 0.30 | 0.25 | 0.05 | 0.4 | 0.5 | 1.5 | 1.0 |
| Example 1 | | | | | | | |
| Comparative | 0.30 | 0.20 | 0.10 | 0.6 | 0.1 | 1.9 | 1.8 |
| Example 2 | | | | | | | |
| Comparative | 0.30 | 0.25 | 0.70 | 0.0 | 1.0 | 1.0 | 0.0 |
| Example 3 | | | | | | | |
| Comparative | 0.35 | 0.25 | 0.60 | 0.4 | 0.7 | 1.3 | 0.6 |
| Example 5 | | | | | | | |
| Comparative | 0.35 | 0.25 | 0.60 | 0.4 | 0.6 | 1.4 | 0.8 |
| Example 5 | | | | | | | |

| | | | | | | Effect |
|---|---|---|---|---|---|---|
| | | | | | | Number of |
| | Evaluation | Relationship between Segment and Substrate | | | | Segments for |
| | of | | Maximum | Length | | which Generation |
| | Backing | Number | Segment | of | | of Cracks |
| | Tube | of | Length | Substrate | | was Confirmed |
| | Warp/mm | Segments | (Lt)/mm | (Lb)/mm | Lt/Lb | during Sputtering |
| Example 1 | 0.2 | 12 | 224.3 | 2,940 | 0.08 | 0 |
| Example 2 | 0.3 | 12 | 224.3 | 2,940 | 0.08 | 0 |
| Example 3 | 0.4 | 12 | 224.3 | 2,940 | 0.08 | 0 |
| Example 4 | 0.5 | 5 | 730.0 | 2,940 | 0.25 | 0 |
| Example 5 | 0.3 | 5 | 312.8 | 1,624 | 0.19 | 0 |
| Comparative | 0.5 | 12 | 246.8 | 2,940 | 0.08 | 3 |
| Example 1 | | | | | | |
| Comparative | 0.9 | 12 | 246.8 | 2,940 | 0.08 | 3 |
| Example 2 | | | | | | |
| Comparative | 0.9 | 12 | 246.8 | 2,940 | 0.08 | 4 |
| Example 3 | | | | | | |
| Comparative | 0.5 | 3 | 897.3 | 2,940 | 0.31 | 1 |
| Example 5 | | | | | | |
| Comparative | 0.5 | 2 | 782.0 | 1,624 | 0.48 | 1 |
| Example 5 | | | | | | |

In Examples 1 to 5, there was no target segment in which cracks were generated during the sputtering, because the maximum quantity of the step difference between the target segments was 0.50 mm or less and the minimum thickness of the bonding material was 0.6 mm or more and 1.4 mm or less.

However, in Comparative Examples 1 and 2, cracks were generated in the three target segments during the sputtering, because the minimum thickness of the bonding material was less than 0.6 mm. In Comparative Examples 3 to 5, the generation of cracks were observed in several target segments during the sputtering, because the maximum quantity of the step difference between the target segments was more than 0.50 mm.

Accordingly, it was found that according to the present invention, even if the backing tube was curved and deformed in the axial direction, the required thickness of the bonding material between the bonding material and the target material could be ensured by a relatively small step difference between the target segments, thereby improving the quality of the bonding of the sputtering target.

### DESCRIPTION OF REFERENCE NUMERALS

1 sputtering target
2 target material
2a target segment
3 backing tube
E1, E2 outer edges of the target segment in the axial direction
Ct distance between adjacent target segments 2a in the axial direction
C1, C2 central points in the cross section from one end to other end of the backing tube
Lt length of a target segment
Lb length of backing tube

1. A sputtering target comprising: a target material made of a ceramic material and comprising a plurality of cylindrical target segments arranged side by side at an interval of from 0.15 mm to 0.50 mm in an axial direction; a cylindrical backing tube arranged on an inner peripheral side of the target material; and a bonding material interposed between the target material and the backing tube to bond the target material to the backing tube,
wherein a quantity of step difference between outer end edges adjacent to each other in the axial direction on respective outer peripheral surfaces of at least a pair of target segments adjacent to each other in the axial direction is 0.50 mm or less as measured along a radial direction, and
wherein a thickness of the bonding material is changed in at least a part of the axial direction within at least one target segment, and the bonding material in the at least one target segment comprises a minimum thickness of 0.6 mm or more and 1.4 mm or less.

2. The sputtering target according to claim 1, wherein the bonding material has a variation of the thickness in the axial direction within the at least one target segment of 0.8 mm or less.

3. The sputtering target according to claim 1, wherein the bonding material in the at least one target segment has a minimum thickness of 0.7 mm or more.

4. The sputtering target according to claim 1, wherein when the backing tube is placed sideways on a surface plate, a maximum distance between a smooth surface of the surface plate and the outer peripheral surface of the backing tube is 0.5 mm or less.

5. The sputtering target according to claim 1, wherein the sputtering target has a ratio of a length of the target segment to a length of the backing tube in a longitudinal direction of 0.3 or less.

6. A method for producing a sputtering target, comprising: a segment arranging step of arranging side by side a plurality of cylindrical target segments made of a ceramic material in an axial direction around a cylindrical backing tube; a bonding material filling step of filling a gap between the backing tube and the target segments with a bonding material in a molten state; and a cooling step of cooling the bonding material and bonding the target segments to a circumference of the backing tube by the bonding material to form a target material,
wherein the method comprises using the backing tube curved and deformed in at least a part of the axial direction,
wherein the method further comprises a deformation quantity measuring step of measuring a quantity of deformation of the backing tube, prior to the segment arranging step, and
wherein the segment arranging step comprises arranging the respective target segments, such that a size of the gap between the backing tube and at least one target segment is 0.6 mm or more and 1.6 mm or less as measured along a radial direction, by adjusting the size of the gap between the backing tube and the at least one target segment depending on the quantity of deformation of the backing tube, and a quantity of step difference between outer end edges adjacent to each other in the axial direction on respective outer peripheral surfaces of at least a pair of target segments adjacent to each other in the axial direction is 0.50 mm or less as measured along the radial direction.

7. The method for producing the sputtering target according to claim 6, wherein the method comprises producing the sputtering target comprising a variation of a thickness of the bonding material in the axial direction within at least one target segment of 0.8 mm or less.

8. The method for producing the sputtering target according to claim 6, wherein the method comprises producing the sputtering target comprising a minimum thickness of the bonding material in the at least one target segment of 0.6 mm or more.

9. The method for producing the sputtering target according to claim 6, wherein the segment arranging step comprises adjusting the size of the gap between the backing tube and the target segments to 0.7 mm or more as measured along the radial direction.

10. The method for producing the sputtering target according to claim 6,
wherein the deformation quantity measuring step comprises placing the backing tube on a surface plate sideways, and measuring a distance between a smooth surface of the surface plate and the outer peripheral surface of the backing tube, and
wherein a maximum distance between the smooth surface of the surface plate and the outer peripheral surface of the backing tube is 0.5 mm or less.
